(19) United States
(12) Patent Application Publication
(10) Pub. No.: US 2025/0132162 A1
(43) Pub. Date: Apr. 24, 2025

(54) SEMICONDUCTOR SUBSTRATE PROCESSING METHOD

(71) Applicant: National Central University, Taoyuan City (TW)

(72) Inventors: Tien-Hsi LEE, Taipei City (TW); CHUN-HUANG WU, Chiayi County (TW); YU-SHENG CHIOU, Chiayi City (TW); SHU-CHENG LI, Dalian City (CN); JING-SYONG HUANG, Changhua County (TW); GUAN-YU LIN, Chiayi County (TW); WEI-CHI HUANG, Taoyuan City (TW)

(21) Appl. No.: 18/633,547

(22) Filed: Apr. 12, 2024

(30) Foreign Application Priority Data
Oct. 20, 2023 (TW) 112140184

(51) Int. Cl. H01L 21/3063; H01L 21/18; H01L 21/67

(52) U.S. Cl. CPC H01L 21/30635; H01L 21/187; H01L 21/67086

(57) ABSTRACT

A semiconductor substrate processing method includes: providing a substrate to be processed, where the substrate to be processed has a side to be processed and a bonding side which are opposite to each other; providing a hole supply substrate; and bonding the hole supply substrate to the bonding side of the substrate to be processed by a wafer bonding process so as to obtain a substrate pair, and performing a material process. By the semiconductor substrate processing method, the purpose of rapid electrochemical etching can be achieved.

### FIELD OF THE INVENTION

The present invention relates to a substrate processing method, and more particularly to a semiconductor substrate processing method.

### BACKGROUND OF THE INVENTION

Main charge carriers of general N-type semiconductor substrates are electrons, if the substrates want to have electrochemical reactions with electrolytes, strong light illumination and transverse electric fields must be applied, or the electrons must be shifted with methods such as the Hall effect and the like, and holes are exposed to interfaces between the N-type semiconductor substrates and the electrolytes, thereby facilitating the electrochemical etching processes.

However, these methods all include environment variables such as distances, intensities and the like which affect the reliability of etching, such that it is an industrial technology trend at present to develop an electrochemical etching technology which does not apply a light source or a biased electromagnetic field.

### SUMMARY OF THE INVENTION

The present invention provides a semiconductor substrate processing method, which can achieve the purpose of rapid electrochemical etching.

The semiconductor substrate processing method provided in the present invention comprises: providing a substrate to be processed, where the substrate to be processed has a side to be processed and a bonding side which are opposite to each other; providing a hole supply substrate; and bonding the hole supply substrate to the bonding side of the substrate to be processed by means of a wafer bonding process so as to obtain a substrate pair, and performing a material process.

In an embodiment of the present invention, the substrate to be processed is an N-type semiconductor substrate, and the hole supply substrate is a P-type semiconductor substrate.

In an embodiment of the present invention, the substrate to be processed is an intrinsic semiconductor substrate, and the hole supply substrate is a P-type semiconductor substrate.

In an embodiment of the present invention, the substrate to be processed is a lightly-doped P-type semiconductor substrate, and the hole supply substrate is a heavily-doped P-type semiconductor substrate.

In an embodiment of the present invention, the hole supply substrate is attached to the substrate to be processed by means of the wafer bonding process.

In an embodiment of the present invention, the material process comprises: placing the substrate pair into an electrolyte to perform an electrochemical process, where the side to be processed has a solid-liquid contact surface in contact with the electrolyte, and the hole supply substrate provides holes for the solid-liquid contact surface so as to complete an anodizing reaction, thereby forming a reaction layer on the side to be processed.

In an embodiment of the present invention, the semiconductor substrate processing method further comprises separating the hole supply substrate from the substrate pair after the reaction layer is formed.

In an embodiment of the present invention, the semiconductor substrate processing method further comprises removing the reaction layer after the reaction layer is formed.

In an embodiment of the present invention, the electrolyte comprises hydrofluoric acid.

In an embodiment of the present invention, in the material process, a semiconductor substrate processing device is suitable for performing an electrochemical process on the substrate pair, and the semiconductor substrate processing device comprises an electrolytic bath, a positive electrode plate and a negative electrode plate. The electrolytic bath is filled with the electrolyte; and the positive electrode plate and the negative electrode plate are respectively disposed on two opposite sides in the electrolytic bath, where the substrate pair is disposed in the electrolyte and located between the positive electrode plate and the negative electrode plate, the substrate to be processed faces the negative electrode plate, the hole supply substrate faces the positive electrode plate, the substrate pair performs the electrochemical process in the electrolyte, the substrate to be processed has the solid-liquid contact surface in contact with the electrolyte, and the hole supply substrate provides the holes for the solid-liquid contact surface so as to perform the anodizing reaction.

In an embodiment of the present invention, the electrolytic bath comprises a bath body, a base and a cover body, the base and the cover body are respectively disposed on a bottom side and a top side of the bath body, and the cover body is provided with an electrolyte access and a gas access.

In an embodiment of the present invention, the semiconductor substrate processing device further comprises two o-rings, an inner surface of the electrolytic bath is provided with a positioning groove which is suitable for clamping and abutting against a periphery of the substrate pair, one of the two o-rings is disposed between a periphery of the side of the substrate pair facing the positive electrode plate and the positioning groove, and the other one of the two o-rings is disposed between a periphery of the side of the substrate pair facing the negative electrode plate and the positioning groove.

In the present invention, a temporary PN junction structure is constructed with a direct wafer bonding technology, such that the purpose of rapid material process (such as electrochemical etching) can be achieved, and unnecessary chemical pollution caused by introduction of impurities does not occur easily. After the material process, the bonded substrate pair can be separated easily so as to remove the hole supply substrate which serves as an intermediate electrode, and the hole supply substrate can also be recycled after being disassembled.

### BRIEF DESCRIPTION OF THE DRAWINGS

The present invention will become more readily apparent to those ordinarily skilled in the art after reviewing the following detailed description and accompanying drawings, in which:

FIGS. 1A-1E are schematic diagrams of the flow of a semiconductor substrate processing method in an embodiment of the present invention;

FIG. 2 is a schematic diagram of a material process of an embodiment of the present invention; and

FIG. 3 is a schematic diagram of an application of a semiconductor substrate processing device in an embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

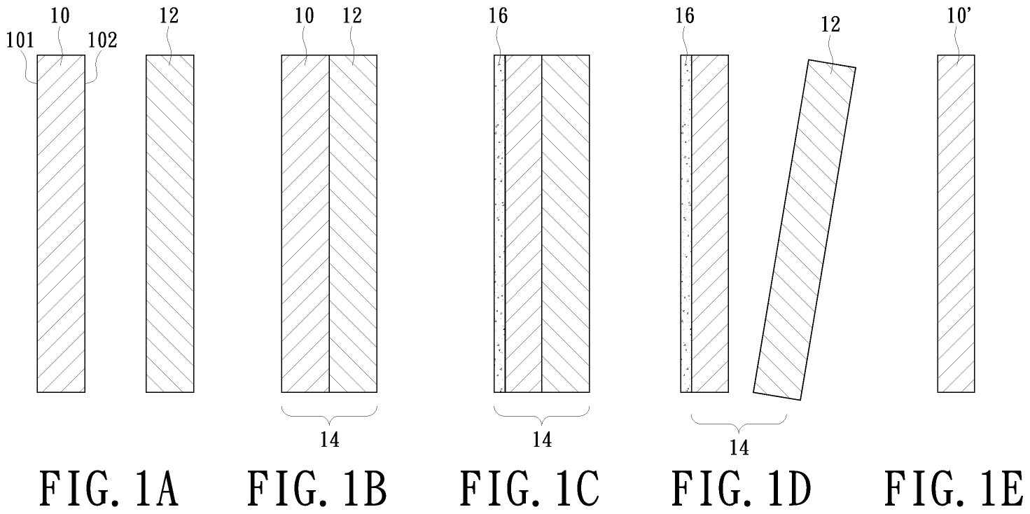

FIGS. 1A-1E are schematic diagrams of the flow of a semiconductor substrate processing method in an embodiment of the present invention. As shown in FIG. 1A, a substrate to be processed 10 and a hole supply substrate 12 are provided, where the substrate to be processed 10 has a side to be processed 101 and a bonding side 102 which are opposite to each other, and the size of the hole supply substrate 12 is identical to or close to that of the substrate to be processed 10. Then, as shown in FIG. 1B, the hole supply substrate 12 is bonded to the bonding side 102 (marked in FIG. 1A) of the substrate to be processed 10 by means of a wafer bonding process so as to obtain a substrate pair 14. Then a material process is performed on the substrate pair 14 so as to form, as shown in FIG. 1C, a reaction layer 16 on the side to be processed 101 (marked in FIG. 1A).

In an embodiment, after the reaction layer 16 is formed, as shown in FIG. 1D, the hole supply substrate 12 is separated from the substrate pair 14. In an embodiment, the reaction layer 16 can be further removed so as to obtain, as shown in FIG. 1E, a thinned substrate 10′.

In an embodiment, before the wafer bonding process is performed on the substrate to be processed 10 and the hole supply substrate 12, a cleaning process and a polishing process can be performed on the substrate to be processed 10 and the hole supply substrate 12 first, and the cleaning process is, for example, an RCA cleaning step; besides, the wafer bonding process is, for example, hydrophobic bonding, the hole supply substrate 12 and the substrate to be processed 10 are attached (bonded) together by means of the van der Waals force, no annealing treatment step is implemented, and the bonding energy does not exceed 120 mJ/m², which is beneficial to separation of the substrate to be processed 10 from the hole supply substrate 12 after the material process.

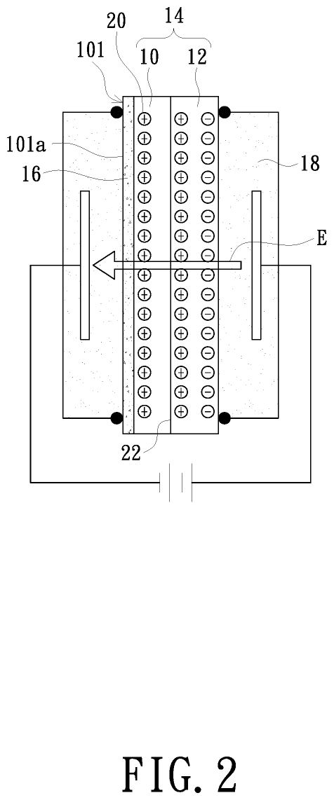

FIG. 2 is a schematic diagram of the material process of an embodiment of the present invention. As shown in FIG. 2, the material process includes placing the substrate pair 14 into an electrolyte 18 to perform an electrochemical process, where the side to be processed 101 of the substrate to be processed 10 has a solid-liquid contact surface 101a in contact with the electrolyte 18, and the hole supply substrate 12 provides holes 20 for the solid-liquid contact surface 101a so as to complete an anodizing reaction, thereby forming the reaction layer 16 on the side to be processed 101. Specifically, in an embodiment, the substrate to be processed 10 is, for example, an N-type semiconductor substrate, the hole supply substrate 12 is, for example, a P-type semiconductor substrate, by means of the wafer bonding process, the substrate to be processed 10 (the N-type semiconductor substrate) and the hole supply substrate 12 (the P-type semiconductor substrate) are attached to each other to form a PN junction 22. Due to the barrier characteristic of the PN junction 22, the role of the holes 20 in the substrate to be processed 10 (the N-type semiconductor substrate) are changed from a secondary carrier flow into a dominant current, thus the holes 20 can be driven by an electric field E to reach the solid-liquid contact surface 101a to generate the anodizing reaction, thereby greatly improving the anodizing efficiency of the side to be processed 101.

In an embodiment, the reaction layer 16 formed on the side to be processed 101 by means of the anodizing reaction is, for example, a weakened layer having a plurality of pores, and the material strength of the weakened layer which is of a hollow spongy structure is greatly lower than that of other solid parts of the substrate to be processed 10, such that the weakened layer can be easily removed in a subsequent process, thereby achieving the effect of thinning the substrate to be processed 10.

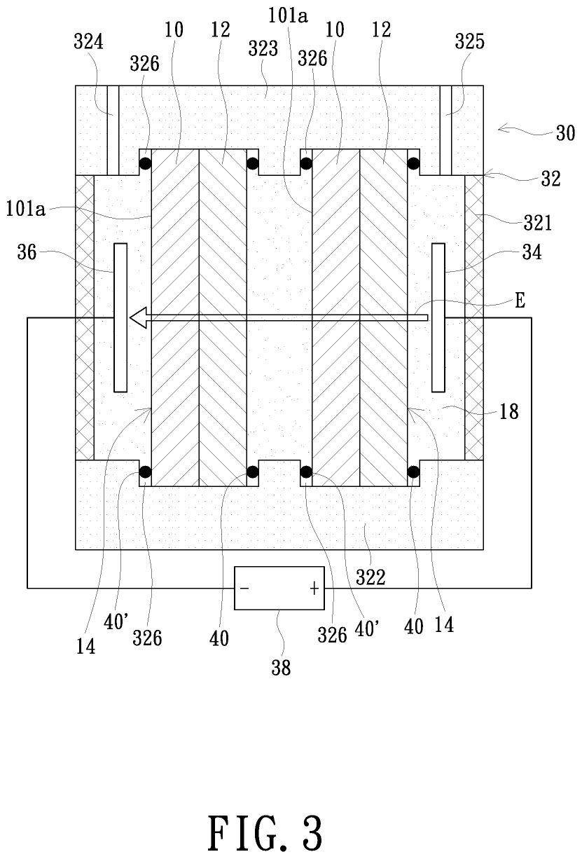

Continuing with the above description, in the material process, a semiconductor substrate processing device in an embodiment of the present invention is configured to perform the electrochemical process on the substrate pair 14. FIG. 3 is a schematic diagram of an application of the semiconductor substrate processing device in the embodiment of the present invention. As shown in FIG. 3, the semiconductor substrate processing device 30 includes an electrolytic bath 32, a positive electrode plate 34 and a negative electrode plate 36. In an embodiment, the electrolytic bath 32 includes, for example, a bath body 321, a base 322 and a cover body 323, the base 322 and the cover body 323 are respectively disposed on a bottom side and a top side of the bath body 321, and the cover body 323 is provided with an electrolyte access 324 and a gas access 325. The electrolytic bath 32 is filled with the electrolyte 18, and the electrolyte 18 includes, for example, hydrofluoric acid (HF); or the electrolyte 18 includes, for example, hydrofluoric acid and ethyl alcohol (C₂H₅OH), and hydrofluoric acid and ethyl alcohol are mixed, for example, in the ratio of 1:1. The positive electrode plate 34 and the negative electrode plate 36 are respectively disposed on two opposite sides in the electrolytic bath 32. In an embodiment, the positive electrode plate 34 and the negative electrode plate 36 are made of, for example, platinum, and the positive electrode plate 34 and the negative electrode plate 36 are further electrically connected to a power supply system 38, such that a required current or voltage is provided by means of the power supply system 38.

When the electrochemical process is performed, the substrate pair 14 is placed in the electrolyte 18 and located between the positive electrode plate 34 and the negative electrode plate 36, the substrate to be processed 10 faces the negative electrode plate 36, and the hole supply substrate 12 faces the positive electrode plate 34; and in the embodiment as shown in FIG. 3, the process for anodizing the two substrate pairs 14 at the same time is taken as an example for description, but it is not limited to this. In the anodizing process, the holes 20 (marked in FIG. 2) provided by the hole supply substrate 12 can be driven by the electric field E to reach the solid-liquid contact surface 101a of the substrate to be processed 10 to generate the anodizing reaction. In an embodiment, in the anodizing process, the appropriate etch rate can be reached by regulating the flow rate of the electrolyte 18; and the arrangement of the electrolyte access 324 and the gas access 325 can match the use of pump (not shown) circulation to freshen the electrolyte 18 and to discharge hydrogen bubbles generated in the reaction process.

Continuing with the above description, in an embodiment, as shown in FIG. 3, the semiconductor substrate processing device 30 further includes a plurality of o-rings 40, 40′, and an inner surface of the electrolytic bath 32 is provided with positioning grooves 326 which are suitable for clamping and abutting against peripheries of the substrate pairs 14. In the embodiment, the positioning grooves 326 are respectively provided in opposite inner surfaces of the base 322 and the cover body 323, each substrate pair 14 is provided with the two o-rings 40, 40′, one o-ring 40 is disposed in a circling manner between a periphery of the side of the substrate pair 14 facing the positive electrode plate 34 and an inner side surface of the positioning groove 326, and the other o-ring 40′ is disposed in a circling manner between a periphery of the side of the substrate pair 14 facing the negative electrode plate 36 and the inner side surface of the positioning groove 326. By means of the arrangement of the o-rings 40, 40′, the electrolytes 18 on two sides of the substrate pair 14 can be prevented from being mixed due to leakage from the positioning grooves 326.

According to the above description, in the semiconductor substrate processing method in the embodiment of the present invention, when the substrate to be processed is the N-type semiconductor substrate and the hole supply substrate is the P-type semiconductor substrate, by means of the wafer bonding process, the P-type semiconductor substrate serves as the intermediate electrode to be attached to the back of the N-type semiconductor substrate so as to form the detachable PN junction, and the PN junction can change the role of holes in the N-type semiconductor substrate from the secondary carrier flow into the dominant current, thereby greatly improving the anodizing efficiency of the surface of the N-type semiconductor substrate. In addition, after the electrochemical etching process is completed, the P-type semiconductor substrate serving as the intermediate electrode can be easily separated from the N-type semiconductor substrate, such that the processed N-type semiconductor substrate is kept pure and free of pollution, and the removed P-type semiconductor substrate can also be recycled.

On the other hand, the substrate to be processed is not limited to the N-type semiconductor substrate, in an embodiment, the substrate to be processed can be a lightly-doped P-type semiconductor substrate, and the hole supply substrate is a heavily-doped P-type semiconductor substrate.

In an embodiment, the substrate to be processed can be an intrinsic semiconductor substrate, for example, a high-impedance silicon crystal, which can be applied to production of high-voltage and high-power components and the like and is an important industrial material for the defense-related science and technology; in addition, the high-impedance silicon crystal, no matter it is in a P-biased type or an N-biased type, is difficult to anodize due to the fact that it is difficult to dissociate the holes from the high-impedance silicon crystal under electric field induction. But, in the semiconductor substrate processing method in the embodiment of the present invention, the heavily-doped P-type semiconductor substrate, for example, heavily-doped P-type silicon, is used as the hole supply substrate, and the high-impedance silicon crystal and the heavily-doped P-type silicon are attached to each other by means of the wafer bonding process, such that the heavily-doped P-type silicon serves as the intermediate electrode to produce the PN junction; and the energy potential of the heavily-doped P-type silicon is biased to a covalent band and is far lower than that of the high-impedance silicon crystal material, such that the holes can be input efficiently under a bias voltage and can move in a manner of migrating between lattices, and thus the holes can be transferred to the solid-liquid contact surface of the high-impedance silicon crystal to perform the anodizing reaction.

Furthermore, in an embodiment, the substrate to be processed can be a silicon carbide single-crystal substrate, and perfect graphene nanoparticles can be obtained by electrolyzing the silicon carbide single-crystal substrate through anodizing with the semiconductor substrate processing method in the embodiment of the present invention. The semiconductor substrate processing method in the embodiment of the present invention has the advantage of low cost, such that a large number of the graphene particles produced from the silicon carbide single-crystal substrate are expected to have broad military and industrial applications.

Furthermore, in an embodiment, the substrate to be processed can be a gallium nitride substrate, porous gallium nitride can be produced by anodizing the gallium nitride substrate with the semiconductor substrate processing method in the embodiment of the present invention, and such material can be used for producing a high-density energy storage device, a strong-light catalytic converter, or a highly-sensitive ultraviolet photoelectric sensor.

According to the above description, in the semiconductor substrate processing method in the embodiment of the present invention, direct wafer bonding technology is used to construct a temporary PN junction structure, such that the purpose of achieving rapid electrochemical etching (such as anodizing) by means of the more rapid arrangement than an epitaxy, diffusion or ion implantation manner can be achieved, and unnecessary chemical pollution caused by introduction of impurities does not occur easily. After anodizing, the bonded substrate pair can be separated easily so as to remove the hole supply substrate which serves as the intermediate electrode, and the hole supply substrate can also be recycled after being disassembled. In addition, for the high-impedance (high-purity) silicon crystal, no matter it is in the P-biased type or the N-biased type, the PN-like junction structure can effectively transport the holes to the solid-liquid contact surface to complete the anodizing reaction. In addition, according to the Fermi level consistency principle in the thermodynamic equilibrium, the semiconductor substrate processing method in the embodiment of the present invention can meet the anodizing requirements of most N-type and even high-resistivity semiconductor substrates in a high efficiency and low energy consumption manner, so as to further build novel nano-structures.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A semiconductor substrate processing method, comprising:
providing a substrate to be processed, wherein the substrate to be processed has a side to be processed and a bonding side which are opposite to each other;
providing a hole supply substrate; and
bonding the hole supply substrate to the bonding side of the substrate to be processed by means of a wafer bonding process so as to obtain a substrate pair, and performing a material process.

2. The semiconductor substrate processing method according to claim 1, wherein the substrate to be processed is an N-type semiconductor substrate, and the hole supply substrate is a P-type semiconductor substrate.

3. The semiconductor substrate processing method according to claim 1, wherein the substrate to be processed is an intrinsic semiconductor substrate, and the hole supply substrate is a P-type semiconductor substrate.

4. The semiconductor substrate processing method according to claim 1, wherein the substrate to be processed is a lightly-doped P-type semiconductor substrate, and the hole supply substrate is a heavily-doped P-type semiconductor substrate.

5. The semiconductor substrate processing method according to claim 1, wherein the hole supply substrate is attached to the substrate to be processed by means of the wafer bonding process.

6. The semiconductor substrate processing method according to claim 1, wherein the material process comprises: placing the substrate pair into an electrolyte to perform an electrochemical process, wherein the side to be processed has a solid-liquid contact surface in contact with the electrolyte, and the hole supply substrate provides holes for the solid-liquid contact surface so as to complete an anodizing reaction, thereby forming a reaction layer on the side to be processed.

7. The semiconductor substrate processing method according to claim 6, further comprising separating the hole supply substrate from the substrate pair after the reaction layer is formed.

8. The semiconductor substrate processing method according to claim 6, further comprising removing the reaction layer after the reaction layer is formed.

9. The semiconductor substrate processing method according to claim 6, wherein the electrolyte comprises hydrofluoric acid.

10. The semiconductor substrate processing method according to claim 1, wherein in the material process, a semiconductor substrate processing device is suitable for performing an electrochemical process on the substrate pair, and the semiconductor substrate processing device comprises:
an electrolytic bath which is filled with an electrolyte; and
a positive electrode plate and a negative electrode plate which are respectively disposed on two opposite sides in the electrolytic bath, wherein the substrate pair is suitable for being disposed in the electrolyte and located between the positive electrode plate and the negative electrode plate, the substrate to be processed faces the negative electrode plate, the hole supply substrate faces the positive electrode plate, the substrate pair performs the electrochemical process in the electrolyte, the substrate to be processed has a solid-liquid contact surface in contact with the electrolyte, and the hole supply substrate provides holes for the solid-liquid contact surface so as to perform an anodizing reaction.

11. The semiconductor substrate processing method according to claim 10, wherein the electrolytic bath comprises a bath body, a base and a cover body, the base and the cover body are respectively disposed on a bottom side and a top side of the bath body, and the cover body is provided with an electrolyte access and a gas access.

12. The semiconductor substrate processing method according to claim 10, wherein the semiconductor substrate processing device further comprises two o-rings, an inner surface of the electrolytic bath is provided with a positioning groove which is suitable for clamping and abutting against a periphery of the substrate pair, one of the two o-rings is disposed between a periphery of the side of the substrate pair facing the positive electrode plate and the positioning groove, and the other one of the two o-rings is disposed between a periphery of the side of the substrate pair facing the negative electrode plate and the positioning groove.
